(19) United States
(12) Patent Application Publication
(10) Pub. No.: US 2010/0206941 A1
(43) Pub. Date: Aug. 19, 2010

(54) COATED DIAMOND

(76) Inventors: David Patrick Egan, County Clare (IE); Kieran Greene, County Clare (IE)

Correspondence Address: FROMMER LAWRENCE & HAUG, 745 FIFTH AVENUE- 10TH FL., NEW YORK, NY, 10151, US

(21) Appl. No.: 12/599,177

(22) PCT Filed: May 22, 2008
(86) PCT No.: PCT/IB2008/052020

§ 371 Date: Mar. 26, 2010

(30) Foreign Application Priority Data
May 22, 2007 (ZA) 2007/04165

(51) Int. Cl. B23K 31/02; B32B 15/04; C23C 16/06; C23C 16/32; C09K 3/14; B24D 3/00

(52) U.S. Cl. 228/221; 428/623; 428/403; 427/404; 427/214; 427/249.1; 51/309; 51/295

(57) ABSTRACT

The invention relates to a coated diamond comprising a diamond substrate; a primary carbided layer of a carbide forming element; a secondary layer of a high melting point metal selected from W, Mo, Cr, Ni, Ta, Au, Pt, Pd or any combination or alloy thereof, the secondary layer being substantially free of carbide forming element from the primary layer; and an overcoat of Ag, Ni, Cu, Au, Pd, Pt, Rh, Os, Tr, Re, any combination or alloy thereof, the metal of the secondary layer being different to the metal of the overcoat. The invention further relates to methods for producing such coated diamonds and abrasive-containing tools including such coated diamonds.

This invention relates to coated diamond particles, methods for production of such coated diamond particles and the use therefore in tools. In particular, this invention relates to diamond particles coated with a primary coating, a secondary coating and an overcoat.

### BACKGROUND OF INVENTION

This invention relates to coated diamond material, a process for the production of such material, and to abrasive-containing tools including such coated diamond material. In particular, this invention relates to coated diamond grit and the use of such grit when brazing in air.

Abrasive particles such as diamond are commonly used in cutting, grinding, drilling, sawing and polishing applications. One of the methods to produce tools for the above applications is brazing. However, in brazing processes, it is difficult to achieve adequate bonding between diamond and the braze material due to the poor wettability of standard brazes on the diamond surface. By contrast, so-called active braze materials contain carbide-forming elements such as Ti or Cr that enable the braze to bond with the diamond surface, allowing uncoated diamond to be brazed in a vacuum furnace. The mechanism for this is the formation of bonds between the carbide-forming elements and the carbon at the diamond surface when the braze alloy is heated to above about 750 deg C. and becomes liquid. This reaction allows the liquid braze alloy to wet the surface of the diamond. When cooled and solidified, the diamond is bonded in place by the solidified braze alloy. The use of a vacuum (or oxygen free atmosphere) is needed to prevent the braze material and diamond from oxidising.

Attempts have been made to put coatings onto the diamond to prevent degradation of the diamond due to oxidation and allow wetting by standard brazes. However, a problem with most coatings is that in the production of tools a non oxidizing environment is required in order to prevent damage to the coating. The non-oxidising environment is usually achieved through either the presence of a strong vacuum, through the use of inert gases such as nitrogen and argon or reducing with hydrogen. The oxidation of the coating can affect both the retention of the coating in the braze and also the wetability of the coating. In addition, any protection offered by the coating may be compromised. Both these occurrences restrict the benefits offered by coatings when brazing in an oxidising environment.

Therefore, brazing is normally undertaken under vacuum with inert gases and very specific brazes, all of which make the brazing process relatively difficult and expensive. Therefore, having a diamond product which could be brazed in air using relatively inexpensive standard braze/flux systems would simplify the brazing process and reduce costs.

In U.S. Pat. No. 5,647,878 (Iacovangelo et al., GE, 1997) and U.S. Pat. No. 5,500,248 (Iacovangelo et al., GE, 1996), the authors describe overcoming the above problems on Chemical Vapour Deposition (CVD) diamond inserts by applying a dual layer coating consisting of a WTi bonding layer and a protective braze compatible overcoat such as Ag. It is shown that the dual-coated diamond insert may be air brazed to a tool substrate in a manufacturing environment using a standard braze without a vacuum furnace or special atmosphere.

In both '878 and '248, the invention is aimed at diamond tool inserts. The substrates mentioned are primarily CVD (i.e. chemical vapour deposited) diamond and PCD (polycrystalline diamond), and all examples use CVD diamond. No mention is given to how the invention could be specifically applied to diamond particulates (better known as grit) or mono crystal diamond. More specifically, no mention is given to either the product of coated grit in particle sizes ranging from 0.01 um to 20 mm. This is significant as such coated grit products would have different applications to CVD diamond and PCD.

In '878 and '248, achieving optimum adhesion between the protective layer and the underlying tungsten-titanium layer involves a very specific heat treatment in a hydrogen-argon mixture with a nitrogen and oxygen getter. In addition, it is critical to have close compositional control over the titanium-tungsten alloy layer to allow a TiC chemical bond to form to the surface of the diamond while preventing Ti migration during heat treatment. As can be understood, the heat treatment and specific compositional control required to produce the product described in both '878 and '248 represents a specific processing route which could be argued to have a relatively high production cost.

In 878 and '248 the coating layers are primarily applied by either CVD (Chemical Vapour Deposition) or PVD (Physical Vapour Deposition). However, when coating grits, as the particle size reduces, the time required to coat the grit, particularly by PVD, increases substantially due to the increase in surface area of the diamond particles. The cost to produce the coated grit then also increases. Therefore, a more cost effective method than PVD is desirable on finer size grit.

In industry there is a high cost associated to holding large amounts of inventory and so there is a drive towards minimizing the amount of inventory which a supplier holds for its customers. However, reducing the level of inventory can have a negative impact on customer lead times unless there is sufficient production capacity available to meet demand. However, having sufficient production capacity usually has an associated high capital cost. Overcoming the above difficulties in having high stocking levels would have an economical benefit to the supplier of coated grits.

It is also desirable to have a product including no or substantially no elemental carbide forming element, for example Ti, which exhibits an affinity for oxidization in the presence of O₂. Such elemental carbide forming element may diffuse through the layers and oxidize. This discolours and comprises the structural integrity of the coating.

### SUMMARY OF INVENTION

According to a first aspect to the present invention there is provided coated diamond comprising:
a diamond substrate;
a primary carbided layer of a carbide forming element,
a secondary layer of a high melting point metal selected from W, Mo, Cr, Ni, Ta, Au, Pt, Pd or any combination or alloy thereof, the secondary layer being substantially free of carbide forming metal from the primary layer and
an overcoat of Ag, Ni, Cu, Au, Pd, Pt, Rh, Os, Ir, Re, any combination or alloy thereof, the metal of the secondary layer being different to the metal of the overcoat.

The term “substantially free” means less than 3% by weight, preferably less than 2.5% by weight, more preferably less than 2% by weight, more preferably less than 1.5% by weight, more preferably less than 1% by weight, more preferably less than 0.5% by weight, more preferably less than 0.2% by weight, more preferably less than 0.01% by weight,

The carbide forming element may be selected from Ti, Cr and Mo.

The diamond substrate is preferably diamond grit and may be selected from diamond derived from high pressure high temperature synthesis techniques, CVD diamond, polycrystalline diamond (PCD), boron doped diamond, mono crystal and natural diamond.

Synthetic diamond abrasive (grit) is produced on a commercial basis using High Pressure and High Temperature (HPHT) through a process in which a graphite source material is dissolved in a solvent metal catalyst.

The catalyst is typically but not limited to Ni, Fe, Co, Mn or combinations thereof. The graphite and catalyst are contained in a reaction volume (capsule) which is placed in a HPHT synthesis press, the capsule is heated resulting in the melting of the solvent catalyst subsequent dissolution of the graphite source takes place creating a super saturated solution of carbon.

The capsule follows a predetermined trajectory into a region of pressure (p), temperature (T) space were the conditions are thermodynamically and kinetically favourable to result in the precipitation of the carbon from the super saturated solution in the form diamond. This process takes place in a region of pT spaces bounded by the eutectic melting line of the chosen catalyst system and the graphite-diamond phase boundary, the locus of which is described by the Berman Simon equilibrium line.

Preferably the diamond grit is in the size range from 0.01 um to 20 mm. This allows the coated diamond grit according to the present invention to be used when manufacturing diamond tools in an oxidising environment. This coated diamond grit eliminates the need for vacuum furnaces when producing sintered segments containing liquid phase infiltrants such as bronzes or when fixing diamond grit to another metallic or cermet material by such methods as brazing.

In a preferred embodiment of the present invention, the primary carbided layer, preferably TiC coating, is applied by either CVD or PVD, the secondary layer, preferably tungsten is applied by PVD or CVD, thus eliminating the need for a heat treatment once coated. The overcoat, preferably Ag may be applied by PVD or electrolytic or electroless deposition.

The TiC coating and/or TiC plus W coating can be standard production items with the result that these materials can be held in stock as standard items with only the addition of an overcoat such as Ag required to produce an air brazeable product, thus minimising costs associated with holding inventory.

According to the present invention, the cost of producing coated diamond grit material are reduced, particularly on finer sizes, by using large scale CVD to produce the TiC coating, applying W by low temperature CVD and applying Ag by electroless or electrolytic deposition.

According to a second aspect to the present invention there is provided a method of producing coated diamond material, the method including the steps of:
providing a diamond substrate;
coating the diamond substrate with a primary carbided layer of a carbide forming element,
coating the primary layer with a secondary layer of a high melting point metal selected from; W, Mo, Cr, Ni, Ta, Au, Pt, Pd or any combination or alloy thereof; and
coating the secondary layer with an overcoat of Ag, Ni, Cu, Au, Pd, Pt, Rh, Os, Ir, Re, any combination or alloy thereof
   the metal of the secondary layer being different to the metal of the overcoat

The carbide forming element may be selected from Ti, Cr and Mo.

The diamond substrate is preferably diamond grit and may be selected from diamond derived from high pressure high temperature synthesis techniques, CVD diamond, polycrystalline diamond (PCD), mono and natural diamond.

In a preferred embodiment of the present invention, the primary carbided layer preferably TiC, is applied by either CVD or PVD, the secondary layer, preferably W coating is applied by PVD or CVD, thus eliminating the need for a heat treatment once coated. The overcoat, preferably Ag coating may be applied by PVD or electrolytic or electroless deposition.

According to a third aspect to the present invention there is provided an abrasive-containing tool including coated diamond grit, mono, CVD diamond and/or PCD according to the present invention.

In a preferred embodiment of this aspect to the invention the abrasive containing tool is selected from segments for saw blades, saw blades per se, drills, beads for diamond wires band saw blades, hacksaws, core drill bits, wire beads, twist drills, wear parts, grinding wheels, grinding tips, rotary dressers, dresser logs for single and multiple log dressers, profile dressers, straight and profiled routers, polishing cups, single point tools, calibration rollers, wire drawing dies, single point turning tools, gauge materials, hard facing or any sintered segment containing coated superabrasives.

According to a fourth aspect of the present invention there is provided the use of coated diamond grit, boron doped diamond, mono crystal, CVD diamond and/or PCD according to the present invention in an oxidative brazing process. The coating may also work in non-oxidising environments such as under vacuum and also in a reducing environment.

### PREFERRED EMBODIMENTS

In accordance with one aspect of the present invention there is provided coated diamond grit in the size ranges from 0.01 um to 20 mm (starting grit, although it will be appreciated by those skilled in the art that there is a negligible difference between starting and finished grit) and also which allows diamond grit to be used when manufacturing diamond tools in an oxidising environment. The coated diamond article preferably consists of a diamond grit substrate, a primary carbided layer of TiC, a secondary layer of W (or another high melting point metal, e.g. Cr or Ni) and an overcoat of Ag.

WO2005078041 (Egan et al. E6, 2005) describes a coating with a primary layer of TiC and a secondary layer of W on diamond grit sizes from 0.1 mm to 10 mm. The product of the present invention includes a silver overcoat on the dual layer product described in WO2005078041 (Egan et al. E6, 2005). The overcoat of Ag prevents oxidation of the W layers. However, the TIC and W layer are needed in order to provide the same benefits as that described in WO2005078041 (Egan et al. E6, 2005). Specifically, the TIC and W combination of coatings is useful where the titanium carbide coating would be reacted away by a constituent of the matrix material during sintering. An example of this would be the use of a liquid infiltrant such as bronze, in the production of a drill crown for mining exploration drilling. In addition, the TiC and W combination is useful where the titanium based coating would be reacted away by brazes used to fix a superabrasive component to another metallic or ceramic material.

The tungsten layer does not have a primary carbided layer, which is not necessary as the purpose of the outer layer is primarily as a barrier for protecting the inner layer and substrate, and sufficient interlayer bonding can be achieved by keeping the tungsten coating thin. The tungsten coating has a thickness of about 0.01 μm to about 50 μm, in particular about 0.2 μm to about 1 μm.

The TiC and W combination is especially useful in the making of diamond impregnated tools such as segments for saw blades, drills, beads for diamond wires especially where high amounts of bronze or copper limit the usefulness of titanium carbide coatings, the making of brazed diamond layer tools such as brazed diamond wire beads, and the making of diamond containing metal matrix composites.

The additional overcoat of Ag on the dual coated TiC plus W product allows for all the above advantages, but with the additional benefit of allowing any such tools to be produced in air, thereby easing manufacturability and reducing costs.

The diamond grit particles are those used conventionally in the manufacturing of metal bonded tools. They are generally uniformly sized, typically 0.01 um to 20 mm. Examples of such diamond grit particles include: Micron grit 0.01 to 60 micron, wheel grit 40 micron to 200 micron, saw grit 180 micron to 2 millimeter, and mono crystal 0.5 millimeter to 200 millimeter.

The diamond particles are first coated in a hot coating process to provide a primary carbided layer of TiC. In this hot coating process, the metal-based coat is applied to the diamond substrate under suitable hot conditions for such bonding to take place. Typically, a range for a hot process would be between 650 deg C. and 1300 deg C. Typical hot coating technologies that can be used include processes involving deposition from a metal halide gas phase, CVD processes or thermodiffusion vacuum coating or metal vapour deposition processes, for example. Deposition from a metal halide gas phase and CVD processes are preferred. Such a hot coating process has been found to be substantially faster and more economical that the prior art favoured PVD method, particularly for fine grit, i.e. grit of size 0.1 to 100 microns, preferably grit of size 10 to 50 microns. Finer coatings may be preferred for such fine grit.

In processes involving deposition from a metal halide gas phase, the particles to be coated are exposed to a metal-halide, for example, titanium chloride, titanium iodide and titanium boride, containing the metal to be coated (e.g. Ti) in an appropriate gaseous environment (e.g. non-oxidising environments containing one or more of the following: an inert gas selected from helium and argon, hydrogen, a hydrocarbon, cracked ammonium or any combination, for example, argon/hydrogen mixture, at a positive pressure, atmospheric pressure or reduced pressure, for example, 10⁻¹ to 10⁻⁷ mBar.) The metal halide may be generated from a metal as part of the process.

The mixture is subjected to a heat cycle, for example, 650 deg C. to 1300 deg C., for 5 min to 10 hrs, 1 to 10 cycles during which the metal-halide transports the Ti to the surfaces of the particles where it is released and is chemically bonded to the particles.

The secondary layer of tungsten can be deposited using a cold coating technique such as low temperature CVD processes or PVD, which is preferred. It is a low temperature process in that insufficient heat is generated to cause significant carbide formation, for example, 650 deg C. Hence, if used alone, it would result in relatively poor adhesion to the diamond particles. An example of a PVD process for applying the outer coating is sputter coating. In this method, a flux of tungsten metal vapour is produced by an excitation source such as a magnetron. Articles such as superabrasive (e.g. diamond) grit or other component placed in the flux become coated with tungsten metal.

The overcoat of Ag can be applied by a cold technique such as PVD or by electrolytic/electroless plating. An example of a PVD process for applying the overcoat is sputter coating. In this method, a flux of silver metal vapour is produced by an excitation source such as a magnetron. Articles such as superabrasive (e.g. diamond) grit or other component placed in the flux become coated with silver metal.

The overcoat of silver can also be applied by electrolytic plating. In this method a quantity, for example, 750 cts of the TiC and W coated grit is placed in a 1.5 litre plating barrel consisting of AgCN, KCN, free KCN, and brightener, for example, Silversene-L (RTM). A silver electrode in the form of rectangular pieces of silver contained in a polypropylene bag is used (purity of the silver was 99.9%). The barrel is rotated at between 1 and 30 rpm, preferably 3 to 10 rpm and a current of 0.1 to 10 Amps, preferably 0.6 to 1.5 Amps is applied in order to plate the surface of TiC and W coated particle with Ag. The duration and temperature of the process was 1 min to 3 weeks at between 1 deg C. and 100 deg C.

The overcoat of silver can also be applied by electroless plating. An example of electroless plating is that following a modified version of that described in ZA8203067 [GE, Ruark & Webster, 1983] and U.S. Pat. No. 4,403,001 [GE, Grenier, 1983] both of which are incorporated herein by reference. This process for coating diamond grit with silver involves suspending diamond grit in an ammoniacal silver solution, preferably by physical agitation thereof, followed by the slow addition of a reducing solution for example invert sugar (mixture of table sugar and nitric acid), thereto while maintaining the agitation and diamond suspension in the silver solution. The metered rate of addition of the reducing solution is carried on until the silver has been coated onto the individual grit and such process repeated until the desired coating weight (or thickness) has been attained.

As the particle diameter decreases the cost of coating by PVD increases substantially. Therefore, from a cost perspective, the preferred method as the particle diameter decreases is to apply the silver overcoat by electroless, electrolytic deposition or a combination of electroless/electrolytic deposition.

As such, the preferred range thickness of the primary coating is 0.01 um (micrometer) to 50 um, preferably 0.3 to 1.2 um.

The preferred range thickness of the secondary coating is 0.01 um to 50 um, preferably 0.3 to 3 um.

The preferred range thickness of the tertiary (for example, Ag) overcoat is 0.01 um to 50 um, preferably 0.3 to 3 um.

The preferred range size of the diamond is:
On grits: 0.01 um to 20 mm;
On mono crystal: 0.5 mm in length to 200 mm
On CVD: 0.5 mm in length to 500 mm or 0.1 um in diameter to 200 um;
On PCD: 0.5 mm in diameter to 1000 mm.

Preferably the secondary layer does not chemically bond to the primary layer, although it will be appreciated that during tool manufacture some bonding may occur.

Preferably the Ag overcoat does not chemically bond to the secondary layer although it will be appreciated that during tool manufacture some bonding may occur.

In each case of coating, preferably the entire diamond is covered but there is always the possibility that there may be gaps in the coating.

Advantages of the product according to the present invention over that taught in the art include:
(1) The invention works better with high temperature brazes as the tungsten in the inventive product is thicker.
(2) The area of chemically bonded first primary layer in the prior art is much less than the TiC layer in the product according to the invention, so better adhesion of TiC layer.
(3) In products taught by the prior art, the Ti in the W layer may act as an oxygen getter and impair brazeability.
(4) The coating as taught in the prior art has not be shown to work on grits or mono crystal.
(5) Close compositional control is required for the prior art product in order to prevent migration of Ti in the Ti/W alloy layer. No such problem exists with the product according to the present invention.

Further advantages associated with the present invention include:
(1) The primary carbided layer does not require a very controlled and costly heat treatment after the coating has been applied.
(2) The method according to the present invention builds upon existing product lines and so reduces the inventory required.

The coated diamond abrasive material (grit) produced according to the present invention is primarily intended for single layer tools or as an alternative to electroplating.

However, in order to highlight the diverse potential of this coating, a non exhaustive list of potential applications is provided below:

Saw blades, band saw blades, hacksaws, core drill bits, wire beads, twist drills, wear parts, grinding wheels, grinding tips, rotary dressers, dresser logs for single and multiple log dressers, profile dressers, straight and profiled routers, polishing cups, single point tools, calibration rollers, wire drawing dies, single point turning tools, gauge materials, hard facing, surface grinders or any sintered/brazed segment containing coated superabrasives, concrete or stone floor grinding and polishing.

One of the advantages of the coating according to the present invention is that it allows for tools to be manufactured by air brazing and in particular to make single layer tools by brazing superabrasives in non-inert atmospheres. This opens up a number of opportunities for novel methods to produce such tools. Techniques which can be used to braze the coated superabrasive article to a tool substrate include: induction heating, standard brazing, blow torching, laser heating, furnace heating, radiant heating and heating using an acetylene torch.

The coated abrasive material according to the present invention may also provide some benefits in other tool making technologies such as hot pressing, free sintering and infiltration sintering. For example, as the coating builds on existing technology such as that described in IE S2004/0024, the coating may offer advantages such as improved wetting, increased retention and/or improved protection when used to producing tool segments by infiltration sintering where liquid phases are typically present.

Other examples of tool manufacturing technologies include but are not limited to electro discharge sintering (EDS), field assisted sintering technology (FAST) and laser sintering. In addition, the coating may open up a different tool manufacturing technology to that currently used to produce existing and new tools which may have an economical benefit to the tool maker.

The coating according to the present invention may potentially offer advantages when joining superabrasive blanks such as PCD and CVD diamond to substrates.

In this specification, the term ‘layer’ and ‘coating’ are used interchangeably.

### EXAMPLES AND SPECIFIC DESCRIPTION

The invention will now be described with reference to the following non-limiting examples and Figures which show:

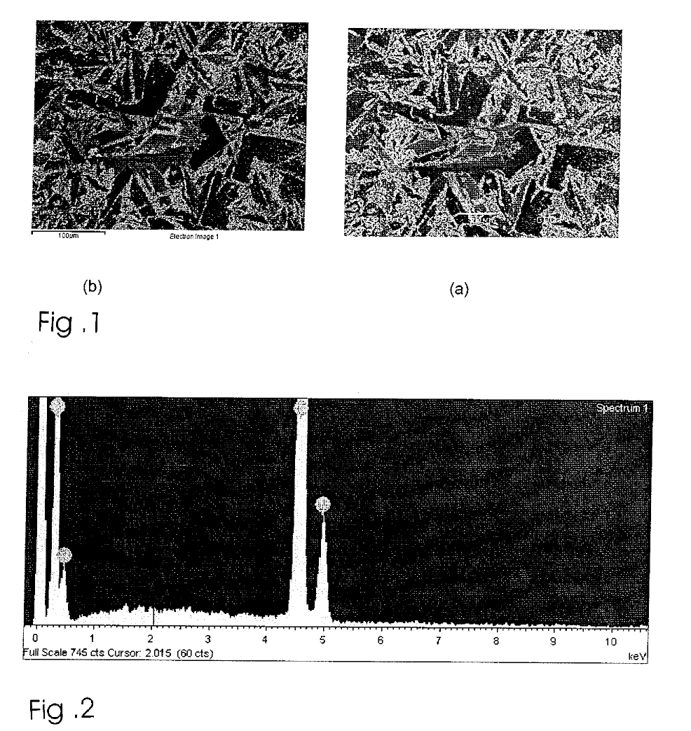

FIG. 1: SEM micrographs of the CDML 301010NPTC7 surface: (a) SEI, (b) BEI.

FIG. 2: Overview EDS spectrum of the surface of CDML 301010NPTC7 corresponding to the area shown in FIG. 1.

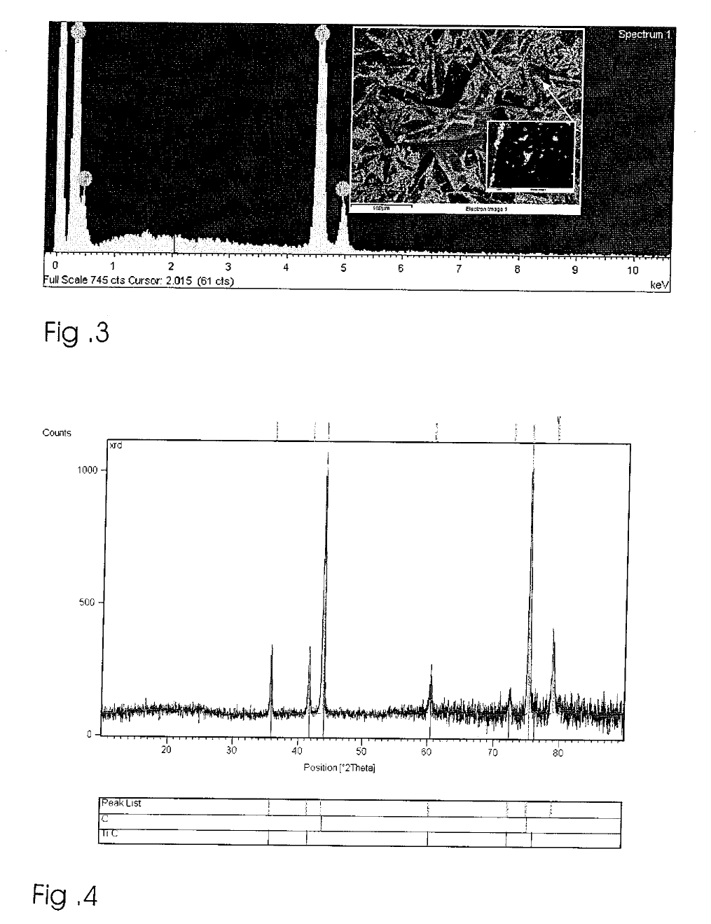

FIG. 3: EDS spectrum of a dark region found on the surface of CDML 301010NPTC7 as indicated by the inset image.

FIG. 4: X-ray diffractogram showing the TiC peaks of CDML 301010NPTC7.

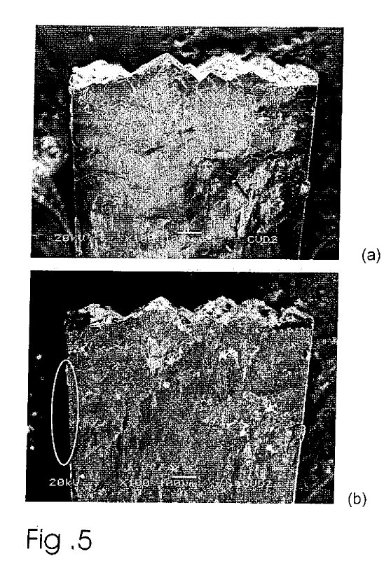

FIG. 5: Cross-sectional SEM micrographs of CDML 301010NPTC7: (a) SEI, (b) BEI.

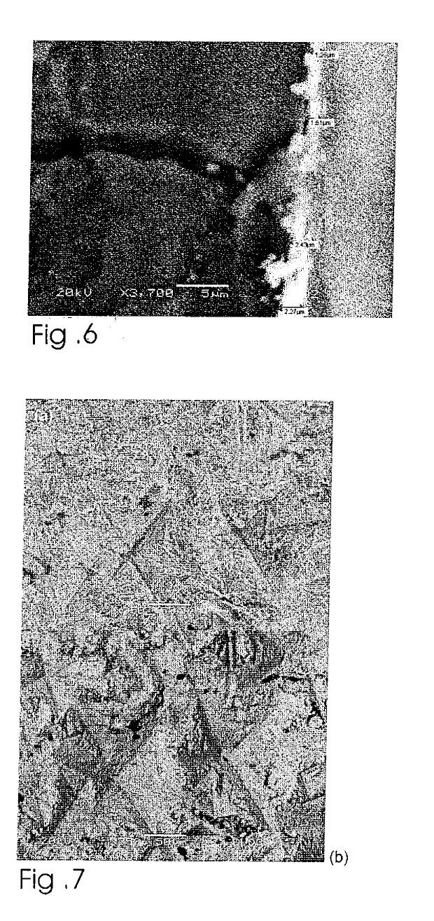

FIG. 6: BEI SEM micrograph showing the coating thickness of CDML 301010NPTC7.

FIG. 7: SEM micrographs of the CDML 301010NPTC12 surface: (a) SEI, (b) BEI.

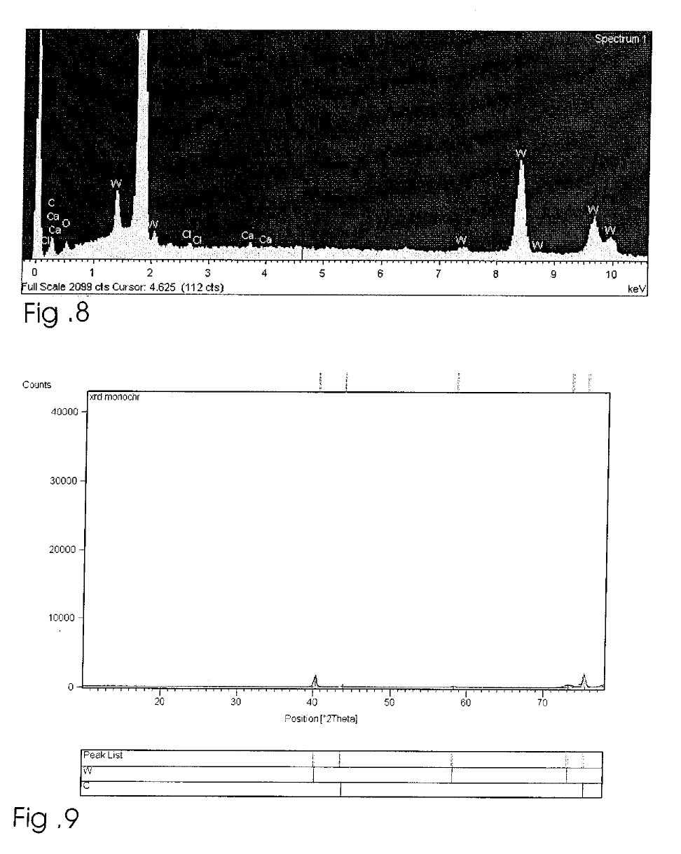

FIG. 8: Overview EDS spectrum of the surface of CDML 301010NPTC12 corresponding to the area shown in FIG. 1.

FIG. 9: X-ray diffractogram showing the W peaks of CDML 301010NPTC12.

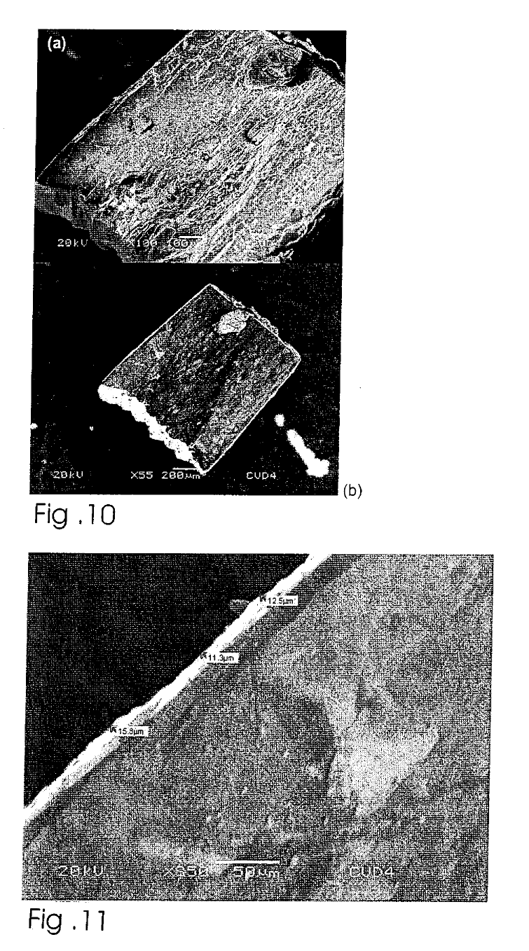

FIG. 10: Cross-sectional SEM micrographs of CDML 301010NPTC12: (a) SEI, (b) BEI.

FIG. 11: BEI SEM micrograph showing the coating thickness of CDML 301010NPTC12.

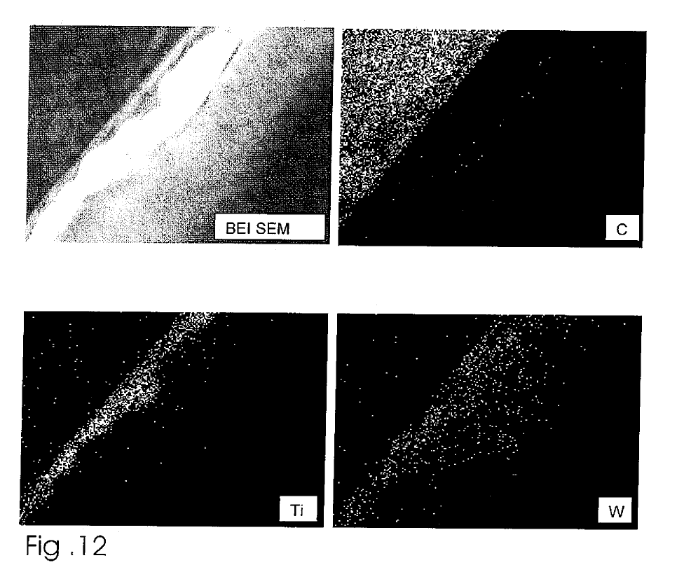

FIG. 12: X-ray map of the BEI SEM micrograph showing the coating composition of CDML 301010NPTC12

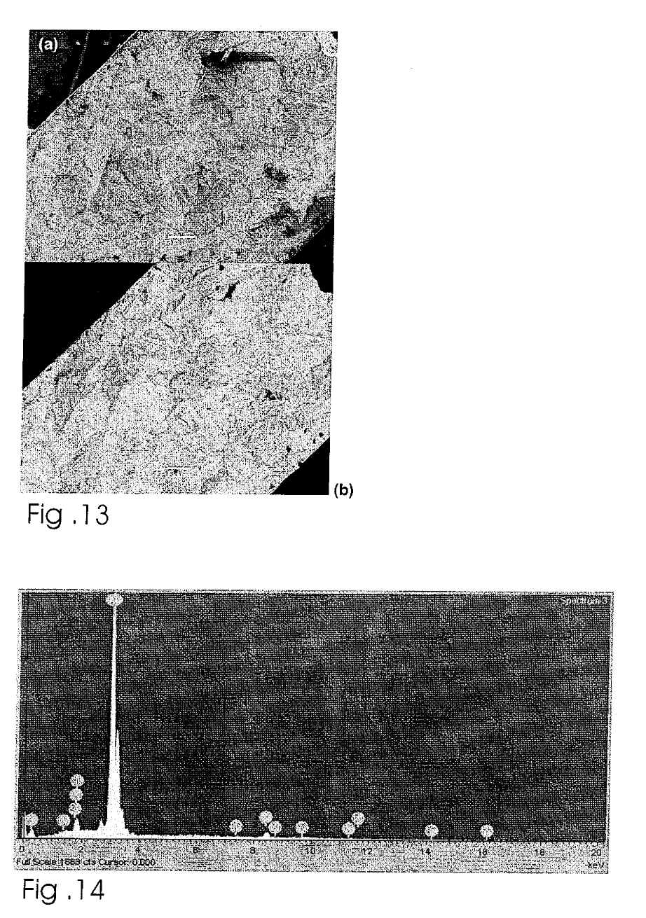

FIG. 13: SEM micrographs of the CDML 301010NPTC18 surface: (a) SEI, (b) BEI.

FIG. 14: Overview EDS spectrum of the surface of CDML 301010NPTC18 corresponding to the area shown in FIG. 1.

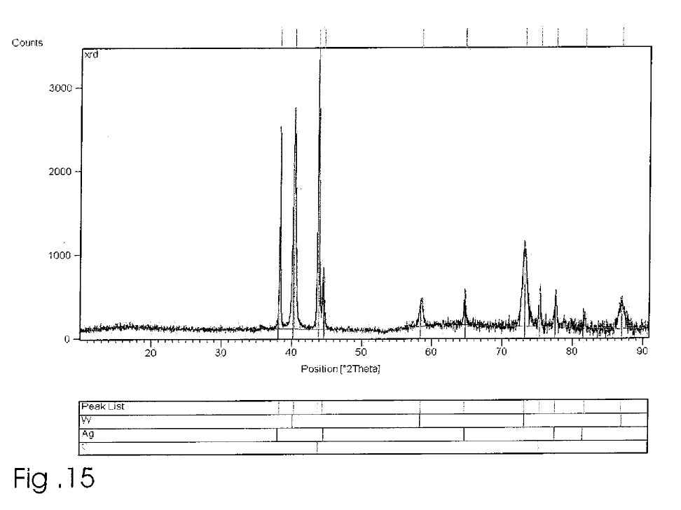

FIG. 15: X-ray diffractogram of CDML 301010NPTC18.

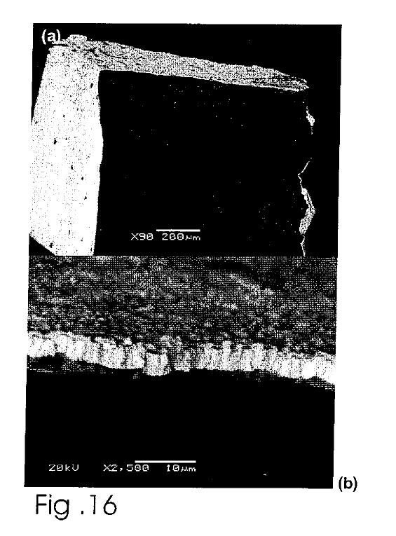

FIG. 16: BEI SEM micrographs showing the cross-section of the CDML 301010NPTC18 coating; (a) overview and (b) close-up.

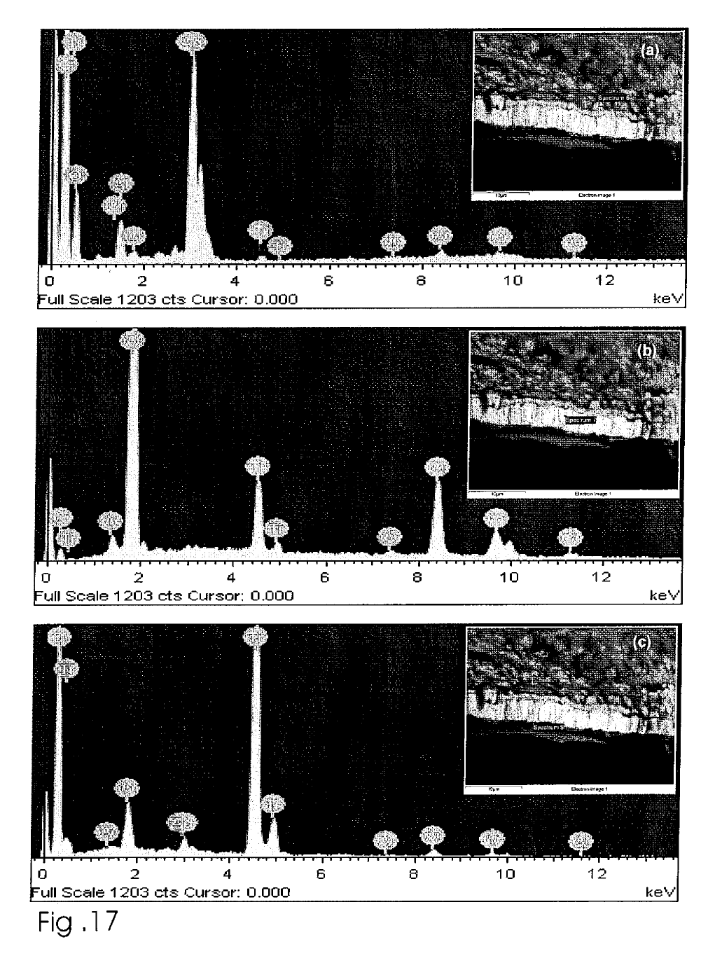

FIG. 17: EDS spectra of the different coating layers; (a) TC18, (b) TC12 and (c) TC7.

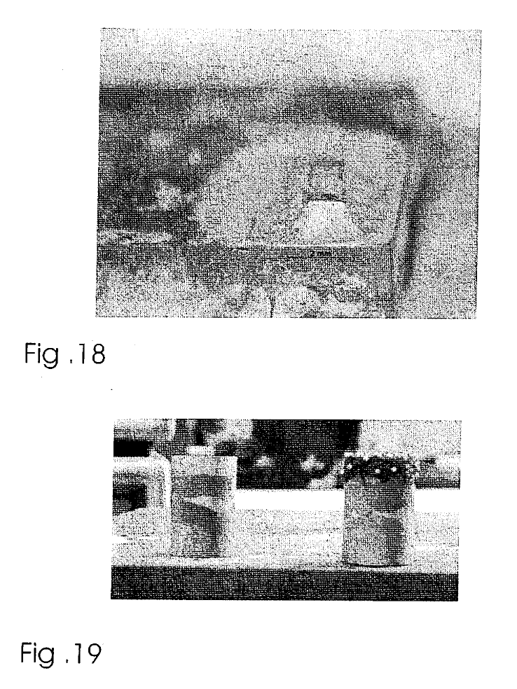

FIG. 18: CDML 301010NPTC18 successfully air brazed to tungsten carbide coupon using Argobraze 49H braze paste.

FIG. 19: Side view of the carbide cylinders used for the brazing tests.

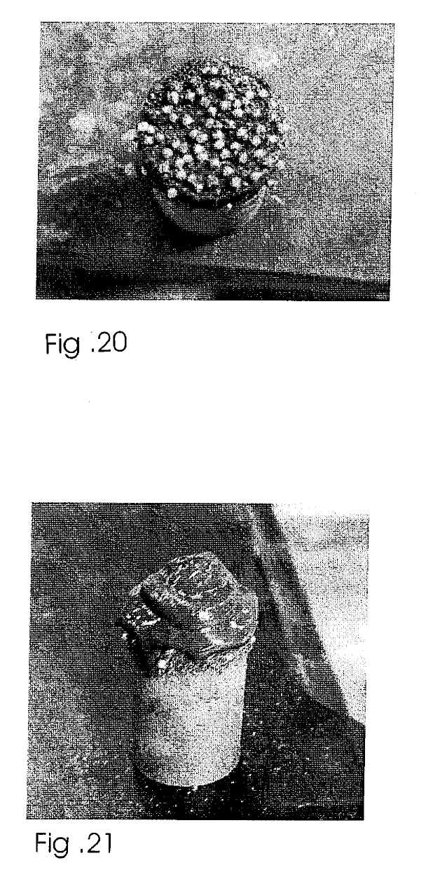

FIG. 20: Top view of coarse coated diamond on the thin braze paste layer to hold the diamond.

FIG. 21: A bead of braze paste has been placed on top of the single layer of diamond on the substrate.

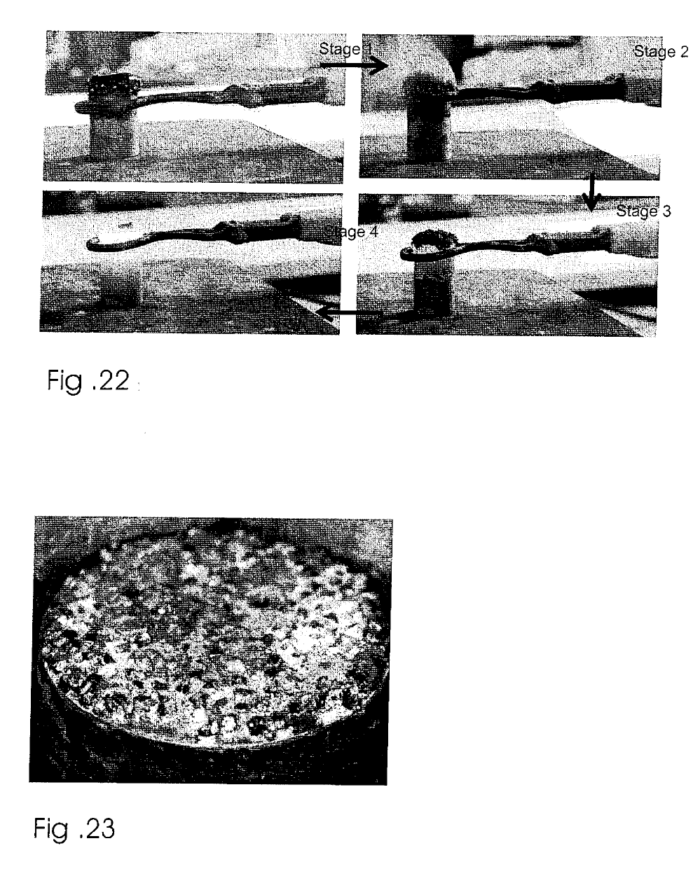

FIG. 22: Stages in the brazing of diamond to a substrate in air.

FIG. 23: Single layer of diamond brazed to a substrate as described above.

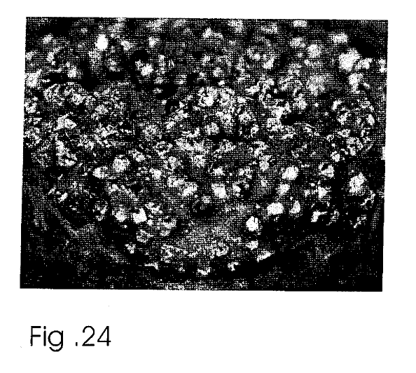

FIG. 24 Diamond particles forming clumps away from the surface.

### EXAMPLE 1

On Element 6 40/45 US Mesh grit three coated products were produced: (1) 0.5 um Ti coating applied by PVD, (2) 0.5 um TiC coating applied by CVD and (3) a coating consisting of a primary layer of TiC by CVD and secondary layer of W by PVD (0.4 um thick).

The coated diamond grit was mixed with braze paste and placed on a tungsten carbide coupon. The coated diamond, braze and coupon were then heated with an induction coil until the braze paste was seen to melt and all the fluxes had been burnt off. Upon cooling the brazed coupon was examined. It was seen in all instances that the braze paste did not wet the surface of the coating Therefore, (1), (2) or (3) cannot be brazed in air as the surface of the coating oxidises and thus prevents wetting of the braze material. The above would be expected to result in poor retention of the diamond in the braze.

### EXAMPLE 2

Using (1), (2) and (3) from Example 1, an overcoat of silver (0.1 um thick) was applied to each coated product by PVD to produce samples no. (4), (5) and (6) respectively. The brazing was performed as outlined in Example 1. In the case of (4) and (5), the braze paste did not wet the surface of the diamond. However, in the case of (3), the coated diamond was wetted by the braze. Therefore, Samples (4) and (5) would be expected to result in poor retention of the diamond in the braze while sample (6) would be expected to have relatively good retention of the diamond in the braze.

### EXAMPLE 3

On Element 6 325/400 US Mesh grit two coated products were produced: (7) a coating consisting of a primary layer of TiC by CVD and secondary layer of W by PVD (0.4 um thick) and (8) a coating consisting of a primary layer of TiC by CVD, a secondary layer of W by PVD (0.4 um thick) and an overcoat of Ag (0.1 um thick) by PVD. The brazing was performed as outlined in Example 1. In the case of (7), the braze paste did not wet the surface of the diamond. However, in the case of (8), the coated diamond was wetted by the braze paste. Therefore, sample (8) would be expected to have relatively good retention of the diamond in the braze.

### EXAMPLE 4

Conventional brazing of diamond requires an active braze material and an oxygen free environment. The active braze contains a carbide former, typically Ti, Cr or Mo which reacts with the diamond surface to promote wetting. An oxygen free environment is required to prevent the active braze material from oxidizing as this precludes wetting. TZ coatings were developed to allow diamond brazing in the presence of oxygen.

TZ air braze-able coatings generally consist of three coating layers—TiC (primary), W (secondary), Ag (overcoat). The TiC layer is chemically bonded to the diamond through a high temperature packed bed diffusion process. The W and Ag layers are applied to the diamond by two separate Physical Vapour Deposition (PVD) cycles.

### Application and Analysis of the TiC Layer

### Procedure for the Application of the TiC Layer

The process parameters used for coating the CDML 301010NP diamond particles with TiC are outlined in Table 1 (below).

TABLE 1
Specifics of process parameters.

| Pot type for hosting diamond | Ti |
|---|---|
| Activator | NH₄I |
| Primary Ti source | Granules |
| Temperature ramp rate (° C. min⁻¹) | 20 |
| Hold temperature (° C.) | 900 |
| Hold time (min) | 240 |
| Hygon gas flow rate (Lmin⁻¹) | 20 |

### Packing and Furnace Run

1. 0.2 g of NH₄I activator was added to a Ti pot that contained 200 g of Ti granules.
2. The resulting composite was mixed well using a Ti bar to stir.
3. 0.22 g of CVD diamonds (20 diamonds) was added to this mixture.
4. The resulting mixture was blended well using a Ti bar to stir.
5. A fine layer of Ti granules was deposited on top of the mixture.
6. The pot was added to a box containing 7 pots of diamond grit that were prepared for the process—the CVD diamond pot was located on the top section of the box.
7. The box was placed on the top shelf of the retort furniture.
8. A cold run was performed.

### Separation and Washing

9. Following the furnace run, the box containing the CVD diamonds was removed from the retort.
10. The pot containing the diamonds was removed from the box and the mixture was loosened from the pot by wedging a chisel between the mixture and the sides of the pot.
11. The mixture was further broken up by hand (sterile gloves were worn).
12. The CVD diamond was separated from the mixture by hand.
13. Two 50 ml beakers were washed with isopropanol.
14. 20 ml of deionised water was poured into one beaker and 20 ml of isopropanol was poured into the other.
15. The CVD diamond was rinsed (by swirling the beaker) in the deionised water and the water was then drained.
16. The isopropanol was then poured onto the CVD diamond.
17. The isopropanol was drained and the CVD diamonds were allowed to dry.
18. Once dry, the CVD diamonds were packaged.

### Analysis of Coated Diamond Particles by the TiC Process

At this stage of the experiment the CVD diamond will be referred to as CDML 301010NPTC7. The CDML 301010NPTC7 sample was inspected visually using the naked eye and two observations were made. Firstly, the coating looked to be ‘patchy’. Secondly, the diamond had a rough side and a polished side. The coating on the polished side of the diamond appeared to have poorer uniformity than on the rest of its surface.

It is suspected that the wet-ability of the diamond is a function of surface roughness and that treating the diamond's surface prior to coating may promote more uniform coverage. As the side with the rough topography showed the most promising results, the surface analysis was undertaken on that side. The rough side of the diamond was also the most easily identified ensuring that like with like comparisons were readily achieved.

Two specimens (one fractured) were sent for SEM, EDS and XRD analysis (AR07IE892). The SEM micrographs of the coating's surface, in FIG. 1, show the highly crystalline nature of the CDML 301010NP and it appears that preferential TiC formation occurs on certain crystallographic facets. Such behaviour has, previously, been observed in the coating of saw grit products and is possibly a consequence of different carbon binding energies between atoms making up the different surface structures (Fries 2001, WP/97/38).

FIG. 2 shows an overview EDS spectrum of the TC7 coated diamond's surface. The counts for Ti are significantly high, which suggests a strong Ti presence on the surface. The darker areas of the BEI SEM image, FIG. 1(b), indicate regions of lower density and, thus, less or no coverage. To check that these darker regions were receptive to the coating, an EDS of such a region was undertaken. The resulting spectrum is shown in FIG. 3 and details comparable Ti counts to those found for the surface overview (FIG. 2). This result implies that, though the BEI image reveals large scale fluctuations in the coating thickness, the overall coverage is good.

XRD examination confirmed that the coating applied by the TC7 process consisted of TiC. The intensity of the TiC peaks, relative to the diamond peaks, suggests that a moderate coating ‘thickness’ was applied. The diffractogram shows an unidentified peak, see FIG. 4, at 79 2theta. The source of this peak is not certain, however, it should be noted that no impurity was detected by EDS, FIGS. 2 and 3.

### Cross-Sectional Analysis of CDML 301010NPTC7

Each end of one of the specimen was held between two vice grips and a bending force was applied until fracture occurred. The fractured surface was analysed to determine the coating's thickness and uniformity. FIG. 5 shows SEI and BEI SEM micrographs of the fractured surface and as expected a brittle type fracture morphology was observed. The BEI SEM micrograph demonstrates the coating clearly and a uniform coating on one side of the specimen was observed, however, on the opposite side of the specimen (circled in FIG. 5(b)) a large window was observed. It is not clear if such windows are an artefact of the coating process or if they are a result of coating delamination during fracture. Coating debris was observed in the close up BEI SEM micrograph of the diamond/coating interface, FIG. 6, which confirms that some level of delamination occurs at fracture.

The coating thickness was measured and the results are presented in FIG. 6. The measurements, of up to 2.43 μm, were surprisingly high as the thicknesses of coatings on saw grit formed by the same process are 0.5 μm. The result alludes to high levels of atomic transport of carbon from the diamond surface and through the formed TiC coating. Another possibility is the formation of pure Ti on the outer surface; this may explain the unidentified XRD peak in FIG. 4.

### Application and Analysis of the W Layer

### Procedure for the Application of the W Layer

0.11 g of CDML 301010NPTC7 was coated with W. The samples were loaded into a PVD unit with a production run of 13,000 ct of SDB1125TC12 20/35. The standard cycle time of 360 mins was run and on completion the CVD diamonds were removed from the rest of the load by hand. At this stage of the experiment the product is referred to as CDML 301010NPTC12

### Analysis of CDML 301010NPTC12 (AR071E956)

Generally, the SEM micrographs in FIG. 7 show that the CDML 301010NPTC12 has been very well coated with W. A number of pit like structures were visible on the SEI image and the BEI image confirmed that these were windows. These windows were relatively small and should not affect the wet-ability of the final product.

The EDS spectrum, presented in FIG. 8, of the region shown in FIG. 7 demonstrated a large number of counts for W which indicated a strong W presence. Trace amounts of Ca and CI were detected by the EDS; however, this seems to be cross contamination as the surface X-ray diffractogram, FIG. 9, did not pick up a phase containing these elements. It is clear from the high intensity W peaks and the no-show of TiC on this X-ray diffractogram that a good coverage of W was achieved.

### Cross-Sectional Analysis of CDML 301010NPTC12

One of the specimens was fractured in a similar manner as for the CDML 301010NPTC7. The fractured surface was analysed to determine the coating's thickness and uniformity. FIG. 10 shows a SEI and a BEI SEM of the CDML 301010NPTC12's fractured surface. The coating appeared uniform and the coverage was good; no windows were apparent.

The combined TiC and W coating thickness was measured to be up to 16 μm, which represents a thick coating, see FIG. 11. The coating appeared well adhered to the CVD diamond and no fracture induced delamination was observed. TiCIW delineation was not conclusive using BEI analysis. Therefore, to confirm the presence of a TiCIW dual layer, the X-ray mapping function of the EDS was used. The X-ray map is presented in FIG. 12 and it confirms the presence of the TiC layer, also noteworthy is the trace levels of C detected in the W layer.

### Application and Analysis of the Ag Overcoat

### Procedure for the Application of the Ag Overcoat

0.05 g of CDML 301010NPTC12 was coated with Ag using the TC18 process. The samples were loaded into a PVD unit with a saw grit production run. The cycle time of 253 mins was run and on completion the CVD diamonds were removed from the rest of the load by hand. At this stage of the experiment the product is referred to as CDML 301010NPTC18.

### Analysis of CDML 301010NPTC18 (AR071E1165)

Surface analysis using an SEM showed that the CDML 301010NPTC18 has been very well coated, see FIG. 13, and EDS, as presented in FIG. 14, confirmed that the coating was Ag. A number of pit like structures were visible on the SEI image and the BEI image confirmed that these were windows. It is interesting to note that some pits showed up as dark regions. Since, the underlying coating is W, which is more dense than Ag, it shows up as bright regions on the BEI micrograph. This suggests that the dark regions are TiC or diamond, an EDS of the pit should identify this region.

The EDS spectrum, FIG. 14, of the region shown in FIG. 13 demonstrated a large number of counts for Ag which indicated a strong Ag presence. Trace amounts of W and C were detected by the EDS indicating that the pits on the surface may well be exposing W and diamond. The X-ray diffractogram presented in FIG. 15 supports the evidence provided by the EDS. It is clear from the high intensity Ag peaks that a good coverage was achieved.

### Cross-Sectional Analysis of CDML 301010NPTC18

One of the specimens was fractured in a similar manner as for the CDML 301010NPTC7. The fractured surface was analysed to determine the coating's thickness and uniformity. FIG. 16 shows SEI and BEI SEM images of the CDML 301010NPTC18's fractured surface. The coating appeared uniform and the coverage was good; no windows were apparent. The Ag overcoat thickness was measured to be ˜1 μm, which represents a ‘thick coating’. In this case, it was not difficult to delineate the coating layers and EDS was undertaken on each layer. These results are shown in FIG. 17. As expected the outer, intermediate and inner layers were Ag, W, TiC respectively. The thickness of the W secondary layer was measured to be 4 μm; this is much lower than that measured on the previous specimen (CDML 301010NPTC12 which was measured to be up to 16 μm) and questions the uniformity of coating thickness between diamonds.

### Brazing Trials

A brazing test in air was performed. Tungsten Carbide coupons were ultrasonically cleaned in Isopronal in order to remove any surface contaminants. A thin layer of Argobraze 49H (Johnson and Matthey) braze paste was placed on the surface of a Tungsten Carbide coupon. A piece of CDML 301010NPTC18 was then placed on top of the layer of the braze paste. Using a high frequency induction coil heater, the assembly of Tungsten Carbide coupon, braze paste and CDML 301010NPTC18 was slowly heated until the braze was seen to melt for approximately 2-5 seconds. The assembly was then allowed to air cool. The resultant brazed component is shown in FIG. 18. It can be seen that CDML 301010NPTC18 shows good wettability and is successfully attached to the Tungsten carbide.

### EXAMPLE 5

This example illustrates how to achieve a single layer of diamond air brazed to a surface. The substrate used is a tungsten carbide cylinder, as shown in FIG. 19. A ring of non-brazeable paint is used to prevent the liquid braze from flowing all over the cylinder. First, a thin layer of braze paste is applied to wherever the diamond is wanted. This acts as a form of sticky layer to hold the diamond. The diamond can be applied by either sprinkling it on top or dipping the substrate into the diamond container. This should yield a single layer of diamond as seen in.

To continue the single layer brazing, a bead of the braze material is placed on top of the layer of diamond on the substrate. This is shown in. It is easiest to add a few drops of white spirit to the braze paste to allow it to flow and essentially pour the bead onto substrate without affecting any of the diamond particles in the single layer.

In this example, a high frequency induction heating unit is used. Any other form of heating could be used, e.g. Oxy-Acetylene torch. It is preferable to heat the substrate and allow this to transfer into the braze. Directly heating the braze is not recommended. The following are the stages in brazing as shown in.
Stage 1. Heating the substrate slowly until the organics begin to burn off.
Stage 2. Keeping the substrate at temperature while the remainder of the organics burn off. In this stage there is a lot of smoke produced and extraction is needed. Also swelling of the braze bead is seen.
Stage 3. The temperature is increased in the substrate to melt the flux and heat the braze.
Stage 4. Heating is increased to melt the braze fully. Be careful not to over-heat the braze material as this will affect bonding and mechanical properties.

By using this method, it is possible to attain a single layer of diamond well bonded to the substrate. Initially, tests were done by mixing the braze paste and diamond together and then applying to the substrate surface. Melting of the braze being done as usual. With this method, the diamond particles form clumps away from the surface which could be easily removed in an abrasive application. An example of this is shown in.

In the above examples, it was found that the coated grit had a bronzy colour and that there may be some oxygen present in the titanium carbide layer. Such oxygen is likely to be present as an oxycarbide and would tend to “anchor” the titanium in the coating and prevent it diffusing into the overcoat layer.

1. A coated diamond comprising:
a diamond substrate;
a primary carbided layer of a carbide forming element,
a secondary layer of a high melting point metal selected from W, Mo, Cr, Ni, Ta, Au, Pt, Pd or any combination or alloy thereof, the secondary layer being substantially free of carbide forming element from the primary layer; and
an overcoat of Ag, Ni, Cu, Au, Pd, Pt, Rh, Os, Ir, Re, any combination or alloy thereof, the metal of the secondary layer being different to the metal of the overcoat.

2. A coated diamond according to claim 1 wherein the carbide forming element is selected from Ti, Cr and Mo.

3. A coated diamond according to claim 1 wherein the diamond substrate is diamond grit selected from diamond derived from high pressure high temperature synthesis techniques, CVD diamond, polycrystalline diamond (PCD), boron doped diamond, mono crystal and natural diamond.

4. A coated diamond according to claim 3 wherein the diamond grit is in the size range from 0.01 um to 20 mm.

5. A coated diamond according to claim 1 wherein the primary carbided layer is applied by either CVD or PVD, the secondary layer is applied by PVD or CVD and the overcoat is applied by PVD or electrolytic or electroless deposition.

6. A coated diamond according to claim 1 wherein the primary carbided layer is titanium carbide, the secondary layer is tungsten and the overcoat is silver.

7. A method of producing coated diamond material, the method including the steps of:
providing a diamond substrate;
coating the diamond substrate with a primary carbided layer of a carbide forming element,
coating the primary layer with a secondary layer of a high melting point metal selected from W, Mo, Cr, Ni, Ta, Au, Pt, Pd or any combination or alloy thereof; and
coating the secondary layer with an overcoat of Ag, Ni, Cu, Au, Pd, Pt, Rh, Os, Ir, Re, any combination or alloy thereof the metal of the secondary layer being different to the metal of the overcoat.

8. A method according to claim 7 wherein the diamond substrate is diamond grit selected from diamond derived from high pressure high temperature synthesis techniques, CVD diamond, polycrystalline diamond (PCD), mono and natural diamond.

9. A method according to claim 7 wherein the carbide forming element is selected from Ti, Cr and Mo.

10. A method according to claim 7 wherein the primary carbided layer is applied by either CVD or PVD, the secondary layer is applied by PVD or CVD and the overcoat is applied by PVD or electrolytic or electroless deposition.

11. A method according to claim 7 wherein the primary carbided layer is titanium carbide, the secondary layer is tungsten and the overcoat is silver.

12. An abrasive-containing tool including coated diamond grit, mono, CVD diamond or PCD according to claim 1.

13. An abrasive-containing tool according to claim 12 selected from segments for saw blades, saw blades per se, drills, beads for diamond wires band saw blades, hacksaws, core drill bits, wire beads, twist drills, wear parts, grinding wheels, grinding tips, rotary dressers, dresser logs for single and multiple log dressers, profile dressers, straight and profiled routers, polishing cups, single point tools, calibration rollers, wire drawing dies, single point turning tools, gauge materials, hard facing and sintered segments containing coated superabrasives.

14. Use of coated diamond grit, boron doped diamond, mono crystal, CVD diamond or PCD according to claim 1 in an oxidative brazing process, in non-oxidising environments including under vacuum and/or in a reducing environment.
